(19) United States
(12) Patent Application Publication
(10) Pub. No.: US 2017/0328800 A1
(43) Pub. Date: Nov. 16, 2017

(54) COMBO MICRO-ELECTRO-MECHANICAL SYSTEM DEVICE AND MANUFACTURING METHOD THEREOF

(71) Applicant: RICHTEK TECHNOLOGY CORPORATION, Zhubei City (TW)

(72) Inventors: Cheng-Syun Li, HsinChu (TW); Chiung-Cheng Lo, Zhunan Township (TW); Chia-Yu Wu, Kaohsiung (TW); Shih-Chieh Lin, Kaohsiung (TW)

(21) Appl. No.: 15/649,062

(22) Filed: Jul. 13, 2017

Related U.S. Application Data
(63) Continuation-in-part of application No. 14/329,111, filed on Jul. 11, 2014.
(60) Provisional application No. 62/376,316, filed on Aug. 17, 2016.
(60) Provisional application No. 62/398,096, filed on Sep. 22, 2016.

(30) Foreign Application Priority Data
May 5, 2017 (CN) 201710312569.5

(51) Int. Cl. G01L 19/00; B81B 7/02; G01L 9/00

(52) U.S. Cl. CPC G01L 19/0092; G01L 9/0072; B81B 7/02; B81B 2203/0127; B81B 2201/025; B81B 2201/0242; B81B 2201/0235; B81B 2203/0353; B81B 2207/11; B81B 2201/0264

(57) ABSTRACT

The invention provides a combo MEMS device. The combo MEMS device includes a substrate, a device layer, a cap, and at least two sensor units. The device layer is on the substrate. The cap is on the device layer. At least two sensor units which are adjacent to each other are both formed by the substrate, the device layer, and the cap. The first sensor unit includes a sealed space, and the second sensor unit includes a membrane and a semi-sealed space. The membrane is formed by reducing a thickness of a portion of the device layer. The semi-sealed space is formed between the substrate and the device layer or between the device layer and the cap, to receive an external pressure through an external pressure communication opening. The external pressure communication opening is formed between the substrate and the device layer, or between the device layer and the cap, or between the substrate and the cap.

### CROSS REFERENCE

The present invention is a continuation-in-part application of U.S. application Ser. No. 14/329,111, filed on Jul. 11, 2014, and claims priority to U.S. provisional application No. U.S. 62/376,316, filed on Aug. 17, 2016, and No. U.S. 62/398,096, filed on Sep. 22, 2016; the present invention also claims priority to China patent application No. 201710312569.5, filed on May 5, 2017.

### BACKGROUND OF THE INVENTION

### Field of Invention

The present invention relates to a combo micro-electro-mechanical system (MEMS) device, in particular a combo MEMS device including at least two sensor units, wherein one of the sensor units includes an external pressure communication opening to receive an external pressure, and the external pressure communication opening is formed between a substrate and a device layer, or formed between the device layer and a cap, or formed between the substrate and the cap.

### Description of Related Art

MEMS devices are commonly used nowadays. Usually, the MEMS device includes a chamber, which includes a membrane or a proof mass therein to generate a sense signal. According to the function that is desired to achieve, the chamber can be completely sealed (such as in accelerator, angular velocity meter, etc.), or semi-sealed in order to receive an external pressure (such as in barometer, microphone, etc.). Usually, the prior art MEMS devices are packaged in such a way that one MEMS device package includes only one single type of sensor unit. However, in order to improve the manufacturing efficiency, there are prior art disclosures proposing to package two different types of MEMS devices in one package, as follows.

FIG. 1 shows a combo MEMS device 10 according to Taiwan patent No. TW I534071, which discloses an integrated structure including a MEMS device 11 with a semi-sealed chamber and a MEMS device 12 with a completely sealed chamber. In the combo MEMS device 10, an external pressure communication opening 111 is formed in a cap by etching, so that the chamber can communicate with an outside pressure. FIG. 1 shows a typical structure to integrate two MEMS devices having a semi-sealed chamber and a completely sealed chamber respectively. U.S. Pat. No. 8,216,882 and German patent No. DE 102014200507 disclose similar structures. The combo MEMS device 10 shown in FIG. 1 has a simple structure; however, particles or dirt may fall in the external pressure communication opening, to adversely affect the sensing accuracy.

FIG. 2 shows a combo MEMS device 20 according to U.S. Pat. No. 9,029,961, wherein it is required for the cap 2 to include a chamfer 21 and a slot 22, so the manufacturing process of the combo MEMS device 20 is very complicated. The slot 22 is provided whereby when the combo MEMS device 20 is cut along the slot 22, the pressure adjustment channel 212 temporarily communicates the chamber 112b of the MEMS device 104b (device 2) to an external pressure source, to adjust a pressure in the chamber 112b. After completing the pressure adjustment, the chamber 112b is sealed, such that the combo MEMS device includes two chambers 112a and 112b with different pressures. In the combo MEMS device 20, the chambers of the MEMS devices 104a (device 1) and 104b (device 2) are both completely sealed, and the MEMS device 104b is only temporarily exposed to the external pressure source through the channel 212 for pressure adjustment.

Other prior art MEMS devices can be found in U.S. patent application Nos. 2013/0001710 and 2015/0260593, wherein U.S. patent application No. 2015/0260593 is filed by the applicant of the present invention, and the present invention is a continuation-in-part application of U.S. patent application No. 2015/0260593.

In short, of the above prior art disclosures, some do not disclose combining MEMS devices having a semi-sealed chamber and a completely sealed chamber into a combo MEMS device, while others disclose combining MEMS devices having a semi-sealed chamber and a completely sealed chamber into a combo MEMS device but do not propose any solution to the problem that particles or dirt may fall in the external pressure communication opening.

### SUMMARY OF THE INVENTION

In one perspective, the present invention provides a combo MEMS device, including: a substrate; a device layer on or above the substrate; a cap on or above the device layer; and at least two sensor units, being adjacent to each other and formed by the substrate, the device layer, and the cap, wherein a first sensor unit includes a first sealed space, and a second sensor unit includes a membrane and a semi-sealed space; wherein, the semi-sealed space is located between the substrate and the device layer, or the semi-sealed space is located between the device layer and the cap, to receive an external pressure through an external pressure communication opening, wherein the external pressure communication opening is formed between the substrate and the device layer, or between the device layer and the cap, or between the substrate and the cap.

In one embodiment, the membrane is formed by reducing a thickness of a portion of the device layer.

In one embodiment, the second sensor unit further includes a second sealed space, which is either completely sealed or further includes an internal pressure communication path communicating with a reference pressure source.

In one embodiment, the second sensor unit further includes a fixed electrode and a movable electrode, to form a sense capacitor for sensing a deformation of the membrane, wherein the fixed electrode or the movable electrode is coupled to a conduction wiring for transmitting a capacitance sense signal from the sense capacitor by sensing the external pressure. In one embodiment, the movable electrode is coupled to a conduction wiring for transmitting a capacitance sense signal from the sense capacitor by sensing the external pressure.

In one embodiment, the fixed electrode is located in the cap and the movable electrode is located in the membrane; or the fixed electrode is located on the substrate and the movable electrode is located in the membrane; or the second sensor unit includes two fixed electrodes which are respectively located in the cap and the substrate, and the movable electrode is located in the membrane.

In one embodiment, the second sensor unit further includes a channel having two sides respectively communicating with the external pressure communication opening and the semi-sealed space, wherein the channel passes through a portion of the device layer which is outside the membrane.

In one embodiment, the device layer is above the substrate, and the external pressure communication opening is formed between the substrate and the device layer. Or in another embodiment, the cap is above the device layer, and the external pressure communication opening is formed between the device layer and the cap.

In one embodiment, the cap includes at least one stopper located on a side of the cap facing the membrane.

In one embodiment, the first sensor unit is a motion sensor unit.

In one embodiment, the second sensor unit is a pressure sensor unit.

In one embodiment, the cap is adhered on the device layer by an adhesive layer.

In one embodiment, the combo MEMS device further including a filter section, which is located between the external pressure communication opening and the semi-sealed space, to form a pressure communication path to communicate the external pressure communication opening and the semi-sealed space. In one embodiment, the external pressure communication opening and the cap are located at a same layer level.

In one perspective, the present invention provides a manufacturing method of combo MEMS device, including: providing a substrate; providing a device layer on or above the substrate, wherein a membrane is formed in the device layer; and providing a cap on or above the device layer; wherein at least two sensor units which are adjacent to each other are formed by the substrate, the device layer, and the cap, wherein the first sensor unit includes a first sealed space, and a second sensor unit includes the membrane and a semi-sealed space, wherein the semi-sealed space includes an external pressure communication opening formed between the substrate and the device layer, to receive an external pressure; or the semi-sealed space includes an external pressure communication opening formed between the cap and the device layer, to receive an external pressure; or the semi-sealed space includes an external pressure communication opening formed between the cap and the substrate, to receive an external pressure.

In one embodiment, the step of providing a device layer further includes: forming a proof mass in the device layer by etching, wherein the proof mass is in the first sensor unit.

In one embodiment, the step of providing a device layer further includes: forming a channel in the device layer, the channel passing through a portion of the device layer which is outside the membrane, the channel having two sides respectively communicating with the external pressure communication opening and the semi-sealed space.

The objectives, technical details, features, and effects of the present invention will be better understood with regard to the detailed description of the embodiments below, with reference to the drawings.

### BRIEF DESCRIPTION OF THE DRAWINGS

FIG. 1 shows a combo MEMS device according to a prior art.

FIG. 2 shows a MEMS device according to another prior art.

FIGS. 3A, 3B, and 3C show a combo MEMS device according to one embodiment of the present invention.

FIGS. 4, 5, and 6 show multiple layouts of the fixed electrodes and the movable electrodes according to various embodiments of the present invention.

FIGS. 7 and 8 show multiple layouts of the channels according to various embodiments of the present invention.

FIGS. 9A, 9B, and 9C show another combo MEMS device according to one embodiment of the present invention.

FIGS. 10A, 10B, and 10C show a layout of the filter section and the external pressure communication opening, according to one embodiment of the present invention.

FIGS. 11A and 11B show another layout of the filter section and the external pressure communication opening, according to one embodiment of the present invention.

FIGS. 12A and 12B show another layout of the filter section and the external pressure communication opening, according to one embodiment of the present invention.

FIGS. 13A, 13B, and 13C show another layout of the filter section and the external pressure communication opening, according to one embodiment of the present invention.

FIGS. 14A-14C, 15A-15D, 16A-16D, and 17A-17D show manufacturing methods of the combo MEMS device according to several embodiments of the present invention.

FIGS. 18A, 18B, 18C, and 18D show a manufacturing method of the combo MEMS device according to one embodiment of the present invention.

### DESCRIPTION OF THE PREFERRED EMBODIMENTS

The drawings as referred to throughout the description of the present invention are for illustrative purpose only, to show the interrelations between the components, but not drawn according to actual scale.

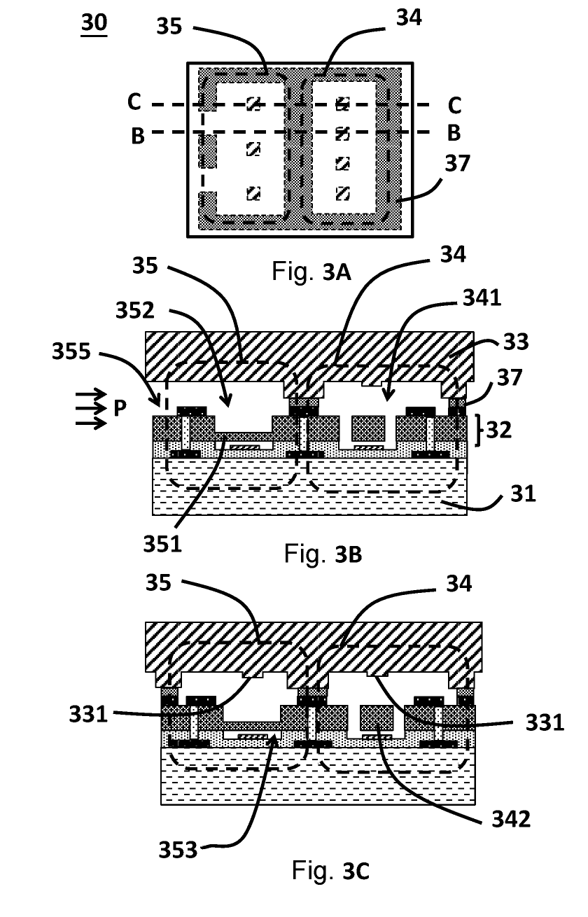

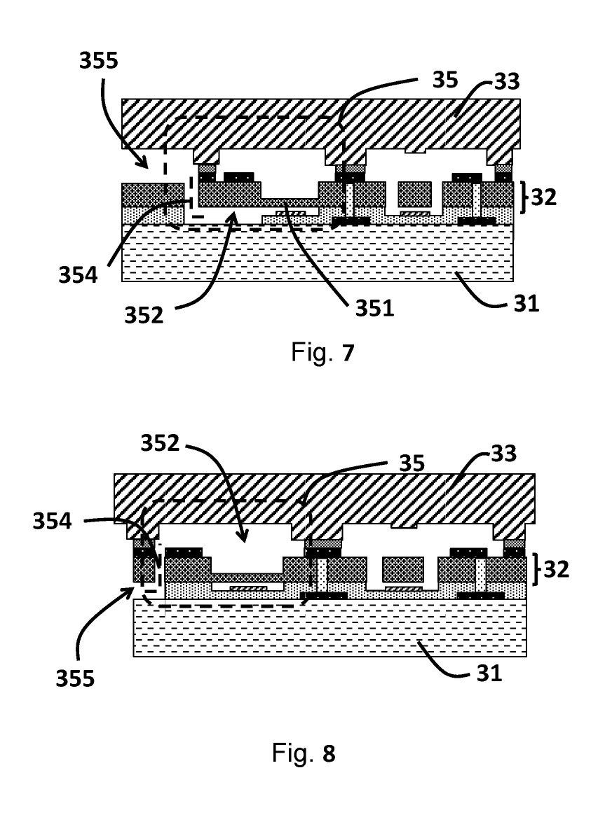

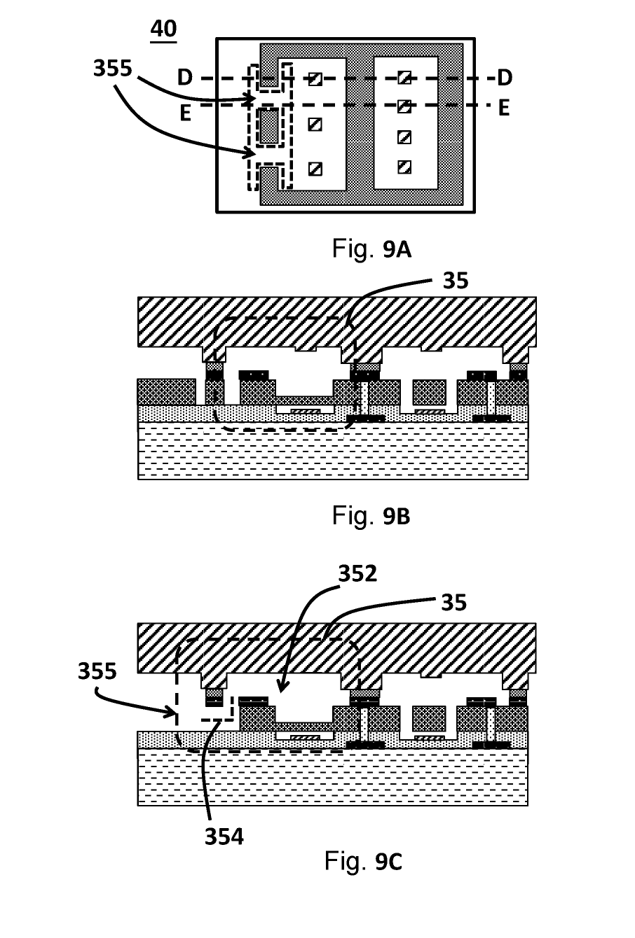

FIGS. 3A, 3B, and 3C show a combo MEMS device 30 according to one embodiment of the present invention. FIG. 3A shows a top view of the combo MEMS device 30, wherein a semi-sealed space and a fully sealed space are located in the combo MEMS device 30. FIGS. 3B and 3C show two cross-section views according to cross-section lines BB and CC shown in FIG. 3A. According to FIGS. 3A, 3B, and 3C, the combo MEMS device 30 includes a substrate 31, a device layer 32, a cap 33, and at least two sensor units 34 and 35. The device layer 32 is located on or above the substrate 31. The cap 33 is located on or above the device layer 32. The two sensor units 34 and 35 which are adjacent to each other are formed by the substrate 31, the device layer 32, and the cap 33, wherein a first sensor unit 34 includes a first sealed space 341, and a second sensor unit 35 includes a membrane 351 and a semi-sealed space 352. The membrane 351 is formed by reducing a thickness of a portion of the device layer 32. The semi-sealed space 352 is formed between the device layer 32 and the cap 33 (in another embodiment shown in FIG. 7, the semi-sealed space 352 is located between the substrate 31 and the device layer 32), to receive an external pressure P through an external pressure communication opening 355. The external pressure communication opening 355 is formed between the device layer 32 and the cap 33 (in another embodiment shown in FIG. 8, the external pressure communication opening 355 is formed between the substrate 31 and the device layer 32; or, in another embodiment shown in FIG. 9C, the external pressure communication opening 355 is formed between the substrate 31 and the cap 33. These embodiments will be explained in detail later). In comparison with the prior art disclosures, the external pressure communication opening 355 of the present invention is not formed in the cap 33, to prevent particles or dirt from easily falling into the semi-sealed space 352.

In one embodiment, the second sensor unit 35 is a pressure sensor unit. In one embodiment, the first sensor unit 34 is a motion sensor unit, which is configured to operably sense a motion status of the combo MEMS device 30 by sensing a motion of a proof mass 342 therein. However, the first sensor unit 34 is not limited to the motion sensor unit. For example, the first sensor unit 34 can be a light sensor unit, a magnetic sensor unit, an electrical sensor unit, a fluid sensor unit, or a temperature sensor unit. The type of the first sensor unit 34 can be decided as desired.

In the aforementioned embodiment of FIGS. 3A, 3B, and 3C, a membrane 351 is formed in one portion of the device layer 32 (if the second sensor unit 35 is a pressure sensor unit), and a proof mass 342 is formed in another portion of the device layer 32 (if the first sensor unit 34 is a motion sensor unit); other electronic components can be formed in the device layer 32, such as one or more field effect transistors, passive or active devices, and/or circuits. In one embodiment, a device or circuit having a piezoresistive effect can be formed in the device layer 32 by doping, and a motion of the membrane 351 in the device layer 32 can be sensed according to the piezoresistive effect.

In one embodiment, the number of the sensor units in the combo MEMS device can be more than two, such as three or more, wherein the third sensor unit can have the same or different function as/from the first or second sensor unit. For example, the third light sensor unit can be a magnetic sensor unit, an electrical sensor unit, a fluid sensor unit, or a temperature sensor unit, etc. The third sensor unit can be located together with the first and the second sensor units in the combo MEMS device. If necessary, besides the first, the second, and the third sensor units, the combo MEMS device can include a fourth sensor unit.

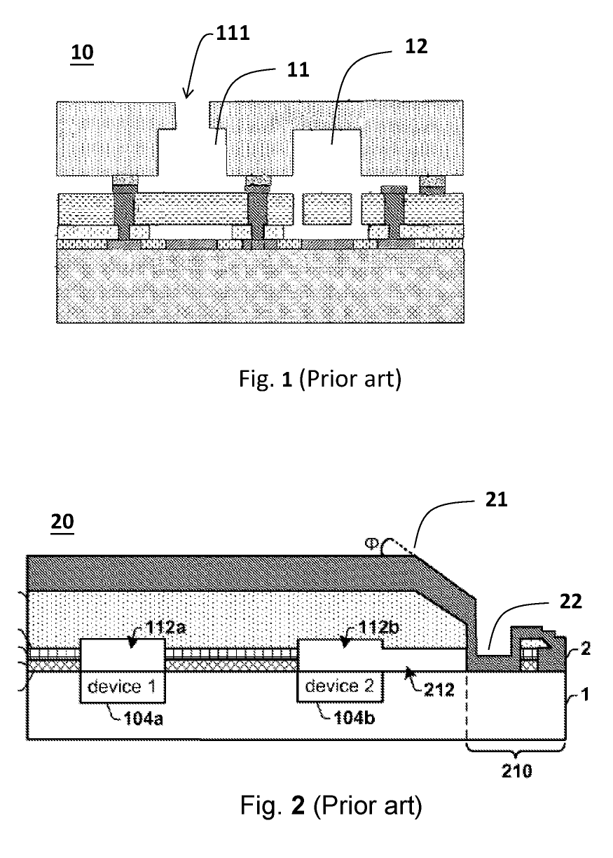

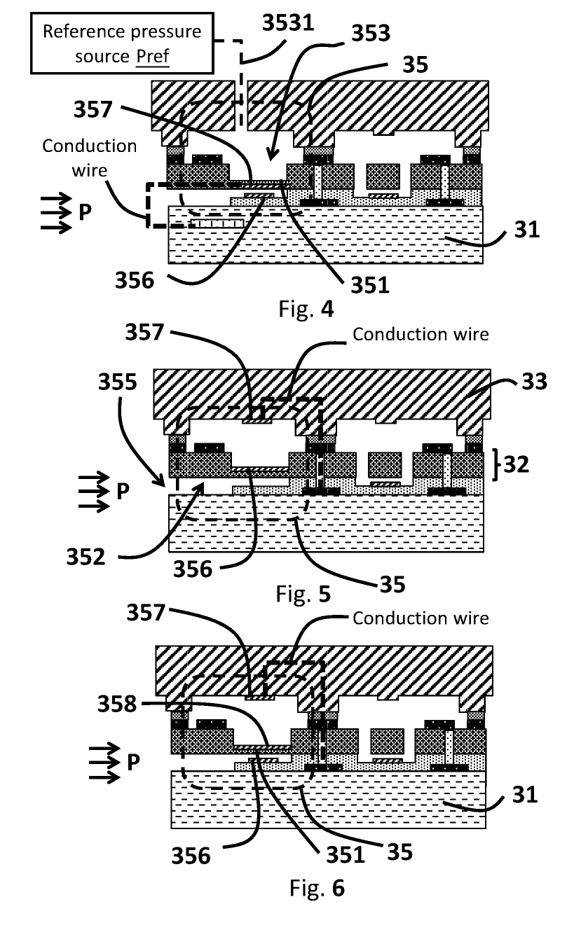

In FIG. 3C, the second sensor unit 35 further includes a second sealed space 353, which is configured to provide a predetermined reference pressure by the completely sealed space design. However, in another embodiment, the second sealed space 353 can be not completely sealed. In FIG. 4, the second sealed space 353 includes an internal pressure communication path 3531 to communicate with a reference pressure source Pref. The internal pressure communication path 3531 is different from the external pressure communication opening 111 in FIG. 1 of the prior art. The external pressure communication opening 111 is exposed to the outside of the combo MEMS device 10, while the internal pressure communication path 3531 communicates the semi-sealed space only with the reference pressure source Pref. The internal pressure communication path 3531 does not communicate the semi-sealed space with the outside of the combo MEMS device. The reference pressure source Pref can provide a predetermined constant or adjustable reference pressure value, and the internal pressure communication path 3531 and the reference pressure source Pref together enable the combo MEMS device 10 to sense a relative pressure value of the external pressure P. If the reference pressure source Pref is vacuum (or if there is no such internal pressure communication path 3531 and reference pressure source Pref), the second sensor unit 35 is designed to sense an absolute pressure value of the external pressure P.

FIGS. 4, 5, and 6 respectively show three embodiments of arrangements of fixed electrodes (356 in FIG. 4, 357 in FIGS. 5 and 6) and movable electrodes (357 in FIG. 4, 356 in FIGS. 5 and 6) in the second sensor unit 35, to form a sense capacitor for sensing a deformation of the membrane 351, wherein the fixed electrode (356 in FIG. 4, 357 in FIGS. 5 and 6) is coupled to a conduction wiring for transmitting a capacitance sense signal from the sense capacitor by sensing the external pressure P. In FIG. 4, the movable electrode 357 located in the membrane 351 and the fixed electrode 356 located on the substrate 31 are configured to sense the deformation of the membrane 351. In FIG. 5, the fixed electrode 357 located in the cap 33 and the movable electrode 356 located in the membrane 351 are configured to sense the deformation of the membrane 351. In FIG. 6, two fixed electrodes 357 are respectively located in the cap 33 and on the substrate 31, forming differential sense capacitors with the movable electrode 358 to sense the deformation of the membrane 351.

The locations of the fixed electrodes and the movable electrodes in FIGS. 3A, 3B, and 3C are omitted for simplicity of the drawings, but one skilled in this art can refer to the embodiments shown in FIGS. 4, 5, and 6 to determine the locations of the fixed electrodes and the movable electrodes in FIGS. 3A, 3B, and 3C, and to sense the deformation of the membranes 351. In the present invention, when the membrane 351 includes a movable electrode, the membrane 351 can include a conductive material or can be made of a conductive material.

In FIGS. 4, 5, and 6, the semi-sealed space 352 is formed between the substrate 31 and the device layer 32, and the external pressure communication opening 355 is formed between the substrate 31 and the device layer 32.

In one embodiment shown in FIG. 7, the second sensor unit 35 includes a channel 354, which has two sides respectively communicating with the external pressure communication opening 355 and the semi-sealed space 352. The channel passes through the device layer 32 in a portion of the device layer 32 which is outside the membrane 351, to communicate the semi-sealed space 352 under the device layer 32 with the external pressure communication opening 355 above the device layer 32. In another embodiment of the present invention, the external pressure communication opening 355 can directly connect the semi-sealed space 352 without the channel in between; the embodiment shown in FIG. 3B is an example.

In FIG. 7, the external pressure communication opening 355 is above the device layer 32, and the semi-sealed space 352 is under the device layer 32. In the embodiment shown in FIG. 8, the external pressure communication opening 355 is under the device layer 32, and the semi-sealed space 352 is above the device layer 32. In FIG. 8, the external pressure communication opening 355 is formed between the device layer 32 and the substrate 31, wherein during a manufacturing process of the combo MEMS device, when the device layer 32 is formed on the substrate 31, the external pressure communication opening 355 is simultaneously formed between the device layer 32 and the substrate 31. Thus, unlike the prior art, no dedicated step such as etching is required in the present invention to form the external pressure communication opening 355. In FIG. 7, the external pressure communication opening 355 is formed between the device layer 32 and the cap 33, and when the cap 33 is formed on the substrate 31, the external pressure communication opening 355 is simultaneously formed between the device layer 32 and the cap 33.

FIG. 9A shows a top view of the combo MEMS device 40 according to one embodiment of the present invention, and FIGS. 9B and 9C are two cross-section views according to the cross-section lines DD and EE shown in FIG. 9A. In FIG. 9C, the external pressure communication opening 355 in the second sensor unit 35 is formed between the substrate 31 and the cap 33, and the external pressure communication opening 355 is communicated to the semi-sealed space 352 through the channel 354.

Please refer to the embodiment in FIG. 3C again, wherein a stopper 331 is formed on a side of the cap 33 facing the membrane 351, for defining an upper limit location to confine the deformation of the membrane 351.

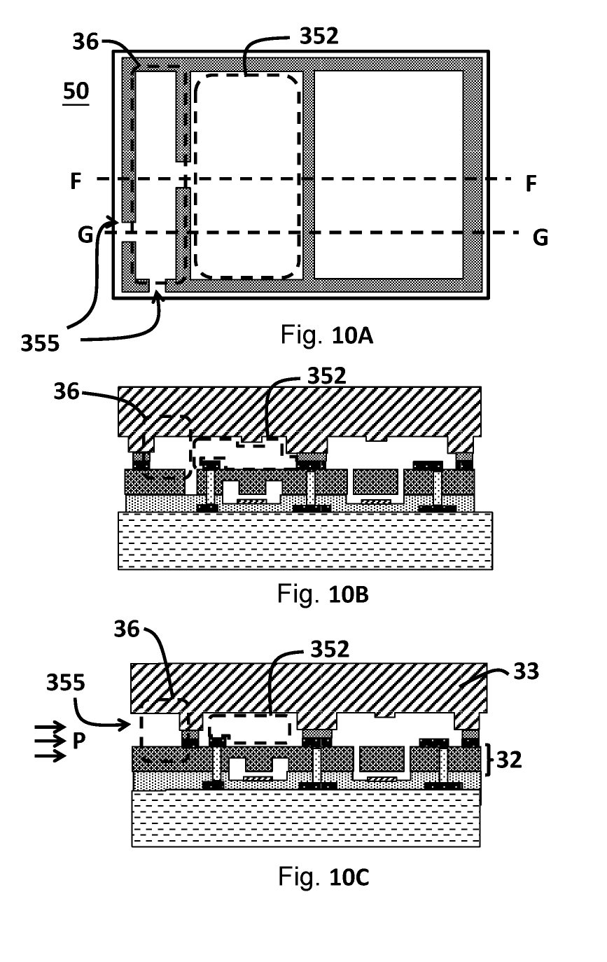

FIG. 10A shows a top view of the combo MEMS device 50 according to one embodiment of the present invention, wherein the combo MEMS device 50 includes a filter section 36 and the semi-sealed space 352. (Stoppers are not shown in FIG. 10A for the simplicity of the drawing.) FIGS. 10B and 10C are two cross-section views according to the cross-section lines FF and GG. In the embodiment of FIGS. 10A, 10B, and 10C, the filter section 36 is located above the device layer 32 and located between the external pressure communication opening 355 and the semi-sealed space 36, to form a pressure communication path between the external pressure communication opening 355 and the semi-sealed space 36. The pressure communication path is located above the device layer 32, for communicating the combo MEMS device 50 with the external pressure, so that the combo MEMS device 50 can sense the external pressure P. According to FIG. 10C, in this embodiment, the external pressure communication opening 355 is located between the device layer 32 and the cap 33.

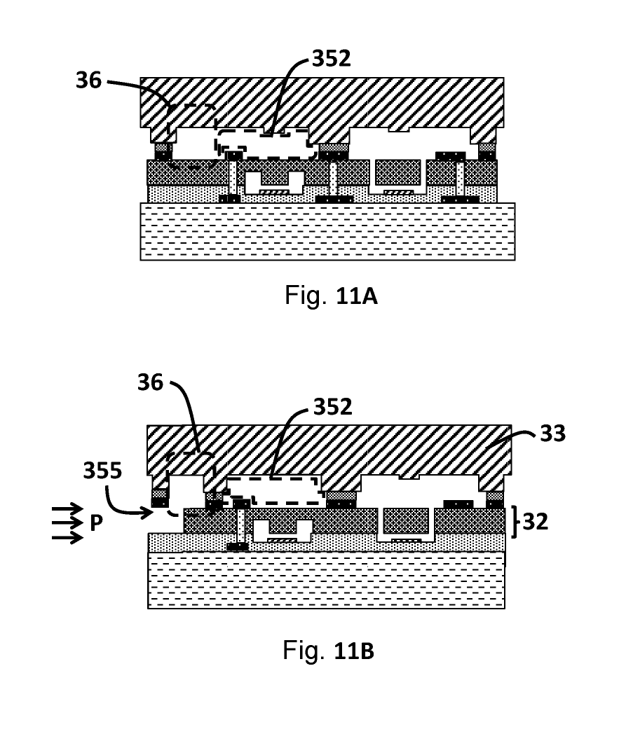

FIGS. 11A and 11B show a layout of the filter section 36 according to another embodiment of the present invention. FIGS. 11A and 11B show different cross-section views according to cross-section lines FF and GG. The filter section 36 is located above the device layer 32, and located between the external pressure communication opening 355 and the semi-sealed space 352, to form a pressure communication path between the external pressure communication opening 355 and the semi-sealed space 352. The pressure communication path passes through the device layer 32 and the filter section 36, to connect the external pressure communication opening 355 (at the same layer level of the device layer 32) to the semi-sealed space 352 (above the device layer 32), for communicating the combo MEMS device 50 with the external pressure, so that the combo MEMS device 50 can sense the external pressure P. According to FIG. 11B, the external pressure communication opening 355 is located between the device layer 32 and the cap 33.

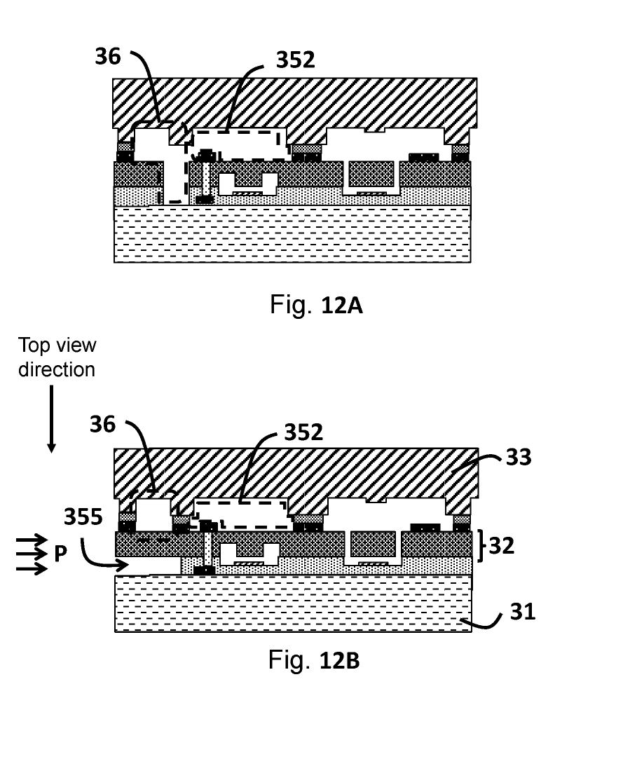

FIGS. 12A and 12B show a layout of the filter section 36 according to another embodiment of the present invention. FIGS. 12A and 12B show cross-section views according to the cross-section lines FF and GG. The filter section 36 is located above the device layer 32 and located between the external pressure communication opening 355 and the semi-sealed space 352, to form a pressure communication path between the external pressure communication opening 355 and the semi-sealed space 36. The pressure communication path passes through the device layer 32 and the filter section 36, to connect the external pressure communication opening 355 (at the same layer level of the device layer 32) to the semi-sealed space 352 (above the device layer 32), for communicating the combo MEMS device 50 with the external pressure, so that the combo MEMS device 50 can sense the external pressure P. According to FIG. 12B, the external pressure communication opening 355 is located between the device layer 32 and the substrate 31, and overlaps with the filter section 36 as seen from the top view direction.

According to the embodiment shown in FIG. 3B, the cap 33 is adhered on the device layer 32 by an adhesive layer 37.

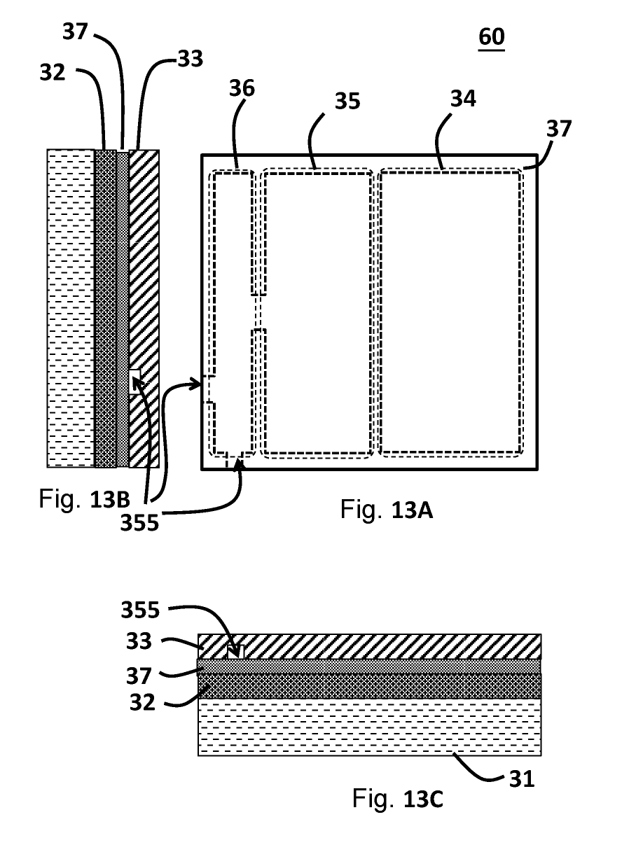

FIG. 13A shows a top view of the combo MEMS device 60, wherein a layout of the filter section 36, the first sensor unit 34 and the second sensor unit 35 of the combo MEMS device 60 are shown. FIGS. 13B and 13C show a left side view and a bottom side projection view corresponding to FIG. 13A. According to the figures, there are two external pressure communication openings 355 on two sides of the filter section 36 (in FIG. 13A, one on the left side of the filter section 36, and one on the lower side of the filter section 36) in the cap 33. The external pressure communication openings 355 and the cap 33 are at a same layer level. This layout to provide two (or more) external pressure communication openings 355 also can be applied to the embodiments shown in FIGS. 3B, 7, and 10C, wherein the cap 33 is located on the device layer 32, and the plural external pressure communication openings 355 are located above the device layer 32.

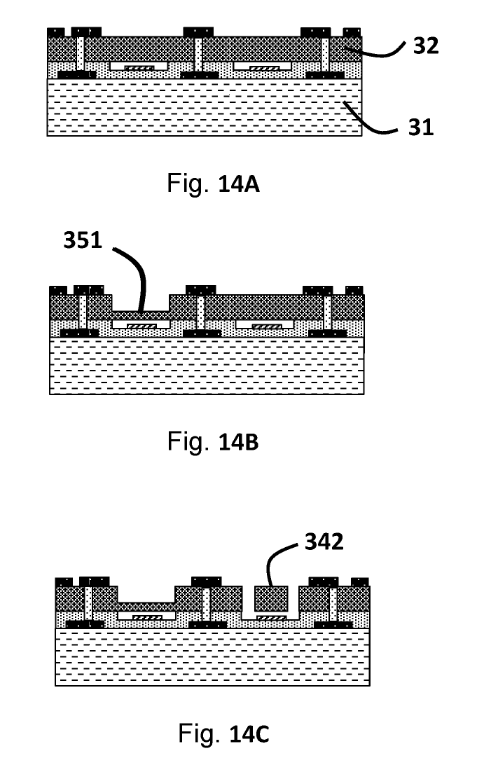

FIGS. 14A, 14B, and 14C show a manufacturing method of a combo MEMS device according to one perspective of the present invention, wherein the manufactured combo MEMS device for example is the combo MEMS device 30 shown in FIG. 3C. The manufacturing method includes: providing a substrate 31; providing a device layer 32 on or above the substrate 31 (FIG. 14A), wherein a membrane 351 is formed in the device layer 32 by reducing a thickness of a portion of the device layer 32 (FIG. 14B); and providing a cap 33 on or above the device layer (FIG. 3C); wherein at least two sensor units 34 and 35 which are adjacent to each other are formed by the substrate 31, the device layer 32, and the cap 33 (FIG. 3C). The first sensor unit 34 includes a first sealed space 341, and the second sensor unit 35 includes the membrane 351 and a semi-sealed space 352. The semi-sealed space 352 includes an external pressure communication opening 355 formed between the cap 33 and the device layer 32, to receive an external pressure P, for communicating the semi-sealed space 352 with the external pressure P, so that the combo MEMS device can sense the external pressure P by the deformation of the membrane 351.

In one embodiment, the first sensor unit 34 is a motion sensor unit. In this embodiment, the aforementioned step of providing the device layer further includes: forming a proof mass 342 (FIG. 14C) in the device layer 32 by etching, wherein when the cap 33 is formed on the device layer 32, the proof mass 342 is defined in the first sensor unit 34 (FIG. 3C).

In the aforementioned manufacturing method embodiment of the combo MEMS device, when the semi-sealed space 352 and the external pressure communication opening 355 are respectively located at two sides of the device layer (e.g. upper and lower sides of the device layer), the step of providing the device layer preferably further includes: forming a channel in the device layer, wherein the channel passes through a portion of the device layer which is outside the membrane, the channel has two sides respectively communicating with the external pressure communication opening and the semi-sealed space, to form a pressure communication path between the external pressure communication opening and the semi-sealed space.

The manufacturing method described above is not limited to manufacturing a combo MEMS device having an external pressure communication opening located between the device layer and the cap. The manufacturing method can manufacture a combo MEMS device having an external pressure communication opening formed between the substrate and the device layer, or having an external pressure communication opening formed between the cap and the substrate.

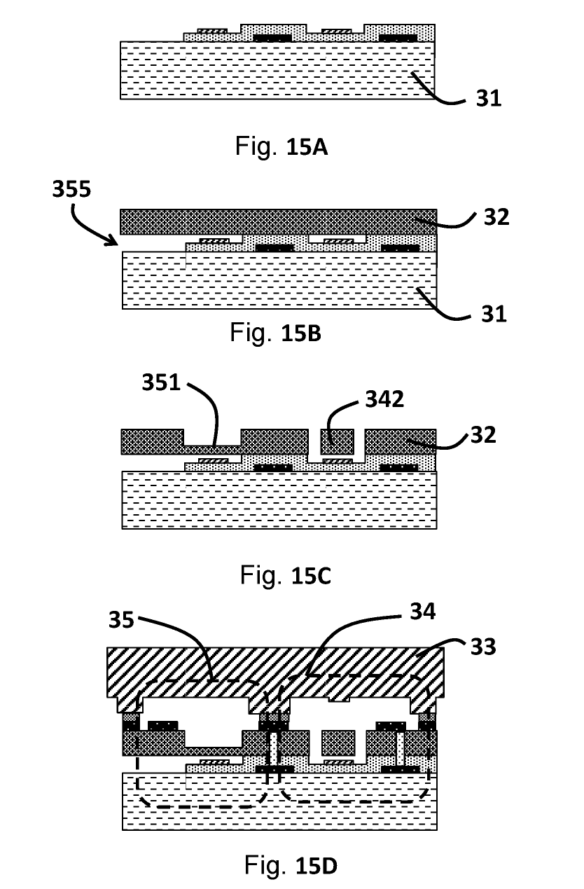

FIGS. 15A, 15B, 15C, and 15D show steps of a manufacturing method of the combo MEMS device according to another embodiment of the present invention, wherein the external pressure communication opening 355 is located between the substrate 31 and the device layer 32. The manufacturing method includes: providing a substrate 31 (FIG. 15A); providing a device layer 32 on or above the substrate 31 (FIG. 15B), wherein a membrane 351 is formed in the device layer 32 by reducing a thickness of a portion of the device layer 32 (FIG. 15C), (and a proof mass 342 can be optionally formed in the device layer 32 if required); and providing a cap 33 on or above the device layer 32. When the device layer 32 is formed on the substrate 31, the external pressure communication opening 355 is simultaneously formed between the substrate 31 and the device layer 32. After the cap 33 is formed on the device layer 32, the at least two sensor units 34 and 35 which are adjacent to each other are simultaneously formed by the substrate 31, the device layer 32, and the cap 33.

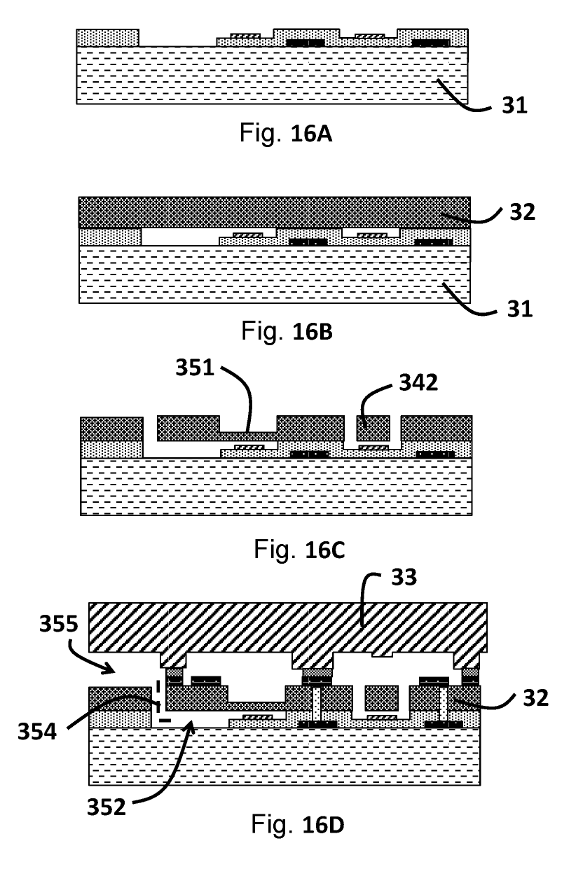

FIGS. 16A, 16B, 16C, and 16D show steps of a manufacturing method of the combo MEMS device according to another embodiment of the present invention, wherein the external pressure communication opening 355 is located between the cap 33 and the device layer 32. The manufacturing method includes: providing a substrate 31 (FIG. 16A); providing a device layer 32 on or above the substrate 31 (FIG. 16B), wherein a membrane 351 and a channel 354 are formed in the device layer 32, the membrane 351 being formed by reducing a thickness of a portion of the device layer 32 (FIG. 16C), (and a proof mass 342 can be optionally formed in the device layer 32 if required), and the channel 354 passing through the device layer 32 to connect the semi-sealed space 352; and providing a cap 33 on or above the device layer 32. After the device layer 32 is formed on the substrate 31 and the cap 33 is formed on the device layer 32, the at least two sensor units 34 and 35 which are adjacent to each other are simultaneously formed by the substrate 31, the device layer 32, and the cap 33. When the cap 33 is formed on the device layer 32, the external pressure communication opening 355 is simultaneously defined between the cap 33 and the device layer 32. According to FIG. 16D, the channel 354 passes through a portion of the device layer 32 which is outside the membrane 351, and the channel 354 has two sides respectively communicating with the external pressure communication opening 355 and the semi-sealed space 352, to form a pressure communication path between the external pressure communication opening 355 and the semi-sealed space 352.

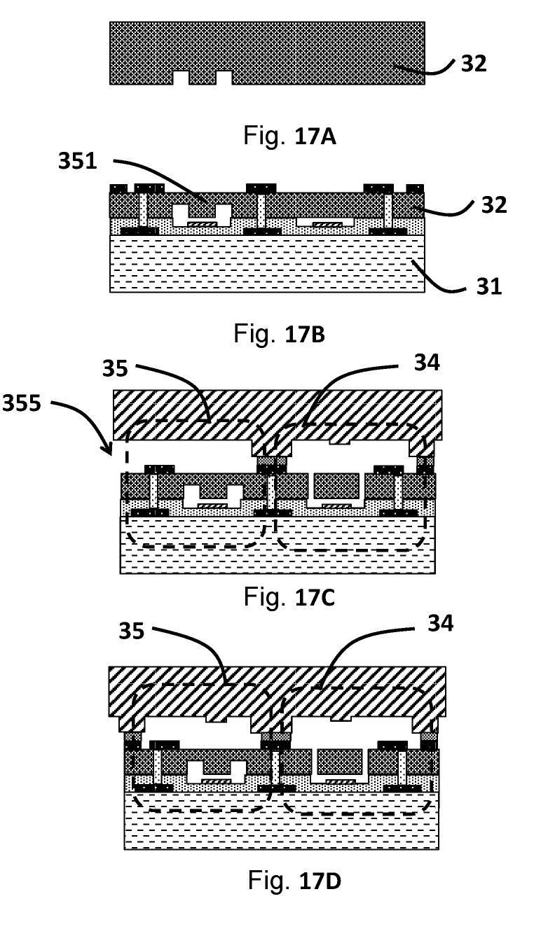

FIGS. 17A, 17B, 17C, and 17D show a manufacturing method of the combo MEMS device according to another embodiment of the present invention. The manufacturing method, similarly to the aforementioned embodiments, includes related steps of providing a substrate 31, a device layer 32, and a cap 33. However, the manufacturing step of the membrane 351 in the device layer 32 is different from that in the aforementioned embodiments, wherein the membrane 351 includes a downward protrusion. According to FIG. 17A, a thinner thickness at the periphery surrounding the downward protrusion is formed by reducing the local thickness of the device layer. Referring to FIG. 17B, the overall thickness of the membrane 351 is obtained by removing a portion of a material of the device layer 32 from the surface of the device layer 32 (for example by grinding, etching, or other process steps capable of removing a material), for example after the device layer is formed on the substrate. After the cap 33 is formed on the device layer 32, FIGS. 17C and 17D show two cross-section views at different locations of the combo MEMS device. FIG. 17C shows a cross-section view wherein the external pressure communication opening 355 is shown. FIG. 17D shows a cross-section view without the external pressure communication opening 355.

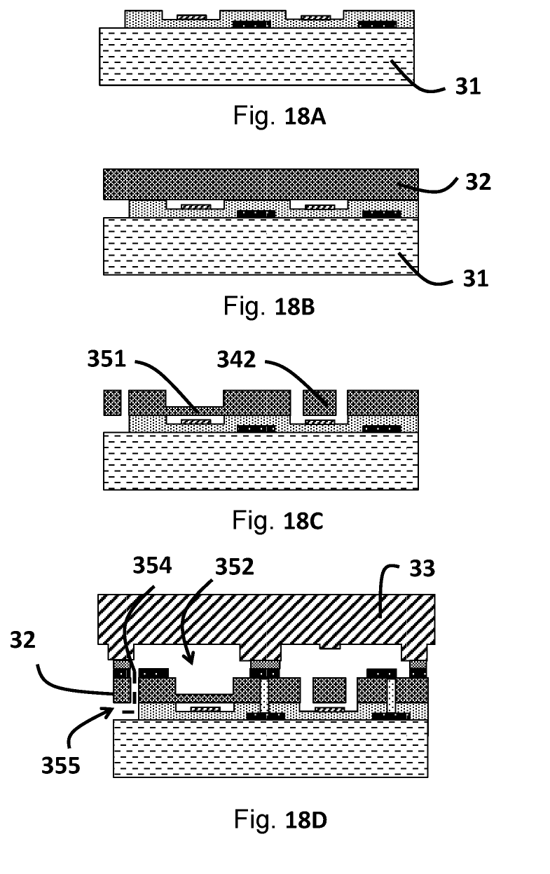

FIGS. 18A, 18B, 18C, and 18D show steps of a manufacturing method of the combo MEMS device according to another embodiment of the present invention, wherein the external pressure communication opening 355 is located between the substrate 31 and the device layer 32. The manufacturing method includes: providing a substrate 31 (FIG. 18A); providing a device layer 32 on or above the substrate 31 (FIG. 18B), wherein a membrane 351 and a channel 354 are formed in the device layer 32, the membrane 351 being formed by reducing a thickness of a portion of the device layer 32 (FIG. 18C), (and a proof mass 342 can be optionally formed in the device layer 32 if required); and providing a cap 33 on or above the device layer 32, wherein the semi-sealed space 352 communicates with the external pressure communication opening 355 through the channel 354. According to FIG. 18D, the channel 354 passes through a portion of the device layer 32 which is outside the membrane 351, and the channel 354 has two sides respectively communicating with the external pressure communication opening 355 and the semi-sealed space 352, to form a pressure communication path between the external pressure communication opening 355 and the semi-sealed space 352.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention; for example, there may be additional devices inserted between two devices shown to be in direct connection in the embodiments, as long as such inserted devices do not affect the primary function of the original devices. Besides, an embodiment or a claim of the present invention does not need to attain or include all the objectives, advantages or features described in the above. The abstract and the title are provided for assisting searches and not to be read as limitations to the scope of the present invention. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment.

What is claimed is:

1. A combo MEMS device, comprising:
a substrate;
a device layer on or above the substrate;
a cap on or above the device layer; and
at least two sensor units (first and second sensor units), being adjacent to each other and formed by the substrate, the device layer, and the cap, wherein the first sensor unit includes a first sealed space, and the second sensor unit includes a membrane and a semi-sealed space;
wherein, the semi-sealed space is located between the substrate and the device layer, or the semi-sealed space is located between the device layer and the cap, to receive an external pressure through an external pressure communication opening, wherein the external pressure communication opening is formed between the substrate and the device layer, or between the device layer and the cap, or between the substrate and the cap.

2. The combo MEMS device of claim 1, wherein the membrane is formed by reducing a thickness of a portion of the device layer.

3. The combo MEMS device of claim 1, wherein the second sensor unit further includes a second sealed space, which is either completely sealed or further includes an internal pressure communication path communicating with a reference pressure source.

4. The combo MEMS device of claim 1, wherein the second sensor unit further includes a fixed electrode and a movable electrode, to form a sense capacitor for sensing a deformation of the membrane, wherein the fixed electrode or the movable electrode is coupled to a conduction wiring for transmitting a capacitance sense signal from the sense capacitor for calculating the external pressure.

5. The combo MEMS device of claim 4, wherein the fixed electrode is located in the cap and the movable electrode is located in the membrane; or the fixed electrode is located on the substrate and the movable electrode is located in the membrane; or the second sensor unit includes two fixed electrodes which are respectively located in the cap and the substrate, and the movable electrode is located in the membrane.

6. The combo MEMS device of claim 1, wherein the second sensor unit further includes a channel having two sides respectively communicating with the external pressure communication opening and the semi-sealed space, wherein the channel passes through a portion of the device layer which is outside the membrane.

7. The combo MEMS device of claim 1, wherein the device layer is above the substrate, and the external pressure communication opening is formed between the substrate and the device layer; or the cap is above the device layer, and the external pressure communication opening is formed between the device layer and the cap.

8. The combo MEMS device of claim 1, wherein the cap includes at least one stopper located on a side of the cap facing the membrane.

9. The combo MEMS device of claim 1, wherein the first sensor unit is a motion sensor unit.

10. The combo MEMS device of claim 1, wherein the second sensor unit is a pressure sensor unit.

11. The combo MEMS device of claim 1, wherein the cap is adhered on the device layer by an adhesive layer.

12. The combo MEMS device of claim 1, further comprising a filter section, which is located between the external pressure communication opening and the semi-sealed space, to form a pressure communication path communicating the external pressure communication opening and the semi-sealed space, wherein the external pressure communication opening and the cap are located at a same layer level.

13. The combo MEMS device of claim 1, further comprising a filter section, which is located between the external pressure communication opening and the semi-sealed space, to form a pressure communication path communicating the semi-sealed space and the external pressure communication opening.

14. A manufacturing method of combo MEMS device, comprising:
providing a substrate;
providing a device layer on or above the substrate, wherein a membrane is formed in the device layer; and
providing a cap on or above the device layer;
wherein at least two sensor units (first and second sensor units) which are adjacent to each other are formed by the substrate, the device layer, and the cap, wherein the first sensor unit includes a first sealed space, and the second sensor unit includes the membrane and a semi-sealed space, wherein the semi-sealed space includes an external pressure communication opening formed between the substrate and the device layer, to receive an external pressure; or the semi-sealed space includes an external pressure communication opening formed between the cap and the device layer, to receive an external pressure; or the semi-sealed space includes an external pressure communication opening formed between the cap and the substrate, to receive an external pressure.

15. The manufacturing method of claim 14, wherein the membrane is formed by reducing a thickness of a portion of the device layer.

16. The manufacturing method of claim 14, wherein the step of providing a device layer further includes: forming a proof mass in the device layer by etching, wherein the proof mass is located in the first sensor unit.

17. The manufacturing method of claim 14, wherein the step of providing a device layer further includes: forming a channel in the device layer, the channel passing through a portion of the device layer which is outside the membrane, the channel having two sides respectively communicating with the external pressure communication opening and the semi-sealed space.
